(19) United States
(12) Patent Application Publication
(10) Pub. No.: US 2025/0286236 A1
(43) Pub. Date: Sep. 11, 2025

(54) Multilayered Flexible Interconnect Circuits with Controllably Interconnectable Busbars and Methods for Operating Thereof

(71) Applicant: CelLink Corporation, San Carlos, CA (US)

(72) Inventors: Gabrielle Tate, Royal Oak, MI (US); Shawn D'Gama, Farmington Hills, MI (US)

(21) Appl. No.: 19/072,440

(22) Filed: Mar. 6, 2025

Related U.S. Application Data
(60) Provisional application No. 63/563,773, filed on Mar. 11, 2024.

(51) Int. Cl. H01M 50/526; G01R 31/388; G01R 31/392; H01M 50/507; H01M 50/516; H01M 50/581; H01M 50/588

(52) U.S. Cl. CPC H01M 50/526; G01R 31/388; G01R 31/392; H01M 50/507; H01M 50/516; H01M 50/581; H01M 50/588; H01M 2220/20

(57) ABSTRACT

Provided are multilayered flexible interconnect circuits comprising a plurality of busbars and a plurality of interconnecting units. The plurality of busbars comprises a first busbar and a second busbar. Each of the plurality of interconnecting units is connected to a first busbar and a second busbar and separately connected to an interconnecting-unit control line. Each of the plurality of interconnecting units is stacked between and connected to each of a portion of the first busbar and a portion of the second busbar. Each of the plurality of interconnecting units maintains electrical disconnection between the first busbar and the second busbar before receiving an electrical input through the interconnecting-unit control line. Each of the plurality of interconnecting units is configured to electrically connect the first busbar and the second busbar after receiving the electrical input through the interconnecting-unit control line.

### CROSS-REFERENCE TO RELATED APPLICATIONS

This application claims the benefit under 35 U.S.C. § 119(e) of U.S. Provisional Patent Application 63/563,773 (Attorney Docket No. CLNKP029P) by Tate, et. al., titled: “Multilayered Flexible Interconnect Circuits with Controllably Interconnectable Busbars and Methods for Operating Thereof”, filed on 2024 Mar. 11, which is incorporated herein by reference in its entirety for all purposes.

### FIELD OF TECHNOLOGY

This patent application relates generally to busbar interconnects, and more specifically to electric vehicle battery busbar interconnects.

### BACKGROUND

Battery cells in battery packs and other types of battery assemblies are typically interconnected using individual busbars. Each busbar is stamped from a sufficiently thick metal sheet (selected based on current ratings) and individually handled during the busbar installation (e.g., positioned over and welded to the battery terminals). Furthermore, additional circuits (e.g., voltage sense harnesses) can be installed and connected to these busbars during the battery pack fabrication. Overall, existing busbars do not provide re-routing of electrical connections to maintain current flow around a failing or failed battery cell within a battery pack.

What is needed is new multilayered flexible interconnect circuits comprising a plurality of busbars and a plurality of interconnecting units capable of selectably interconnecting individuals of the plurality of busbars, battery backs comprising such multilayered flexible interconnect circuits, and methods for operating thereof.

### SUMMARY

Provided are multilayered flexible interconnect circuits comprising a plurality of busbars and a plurality of interconnecting units. The plurality of busbars comprises a first busbar and a second busbar. Each of the plurality of interconnecting units is connected to a first busbar and a second busbar and separately connected to an interconnecting-unit control line. Each of the plurality of interconnecting units is stacked between and connected to each of a portion of the first busbar and a portion of the second busbar. Each of the plurality of interconnecting units maintains electrical disconnection between the first busbar and the second busbar before receiving an electrical input through the interconnecting-unit control line. Each of the plurality of interconnecting units is configured to electrically connect the first busbar and the second busbar after receiving the electrical input through the interconnecting-unit control line.

Clause 1. A multilayered flexible interconnect circuit comprising: a plurality of busbars, comprising a first busbar and a second busbar, wherein each one of the plurality of busbars is defined by a contact portion, a first tab portion, and a second tab portion; a plurality of interconnecting-unit control lines, comprising an interconnecting-unit control line; and a plurality of interconnecting units, wherein: each one of the plurality of interconnecting units is stacked between and connected to each of the first tab portion of one of the plurality of busbars and the second tab portion of another one of the plurality of busbars and separately connected to an interconnecting-unit control line, each one of the plurality of interconnecting units is configured to electrically disconnect the first tab portion and the second tab portion before receiving an electrical input through the interconnecting-unit control line, and each one of the plurality of interconnecting units is configured to electrically connect the first tab portion and the second tab portion after receiving the electrical input through the interconnecting-unit control line.

Clause 2. The multilayered flexible interconnect circuit of clause 1, wherein each one of the plurality of interconnecting units is a transistor comprising: a source electrically interconnected with either the first tab portion of the first busbar and the second tab portion of the second busbar, a drain electrically interconnected with the other of either the first tab portion of the first busbar and the second tab portion of the second busbar, and a gate electrically interconnected with the interconnecting-unit control line, wherein: each transistor is configured to reversibly electrically connect the first busbar and the second busbar after receiving the electrical input through the interconnecting-unit control line.

Clause 3. The multilayered flexible interconnect circuit of clause 1, wherein each one of the plurality of interconnecting units is a normally-open relay comprising: a first pole electrically interconnected with either the first tab portion of the first busbar and the second tab portion of the second busbar, a second pole electrically interconnected with the other of either the first tab portion of the first busbar and the second tab portion of the second busbar, and an actuation lead electrically interconnected with the interconnecting-unit control line, wherein: each normally-open relay is configured to reversibly electrically connect the first busbar and the second busbar after receiving the electrical input through the interconnecting-unit control line.

Clause 4. The multilayered flexible interconnect circuit of clause 1, wherein each one of the plurality of interconnecting units is a heat-actuated interconnector comprising: a first connecting portion electrically interconnected with either the first tab portion of the first busbar and the second tab portion of the second busbar, a second connecting portion electrically interconnected with the other of either the first tab portion of the first busbar and the second tab portion of the second busbar, a meltable portion positioned between the first connecting portion and the second connecting portion, and a heating element electrically interconnected with the interconnecting-unit control line, wherein: the heating element is configured to melt the meltable portion after receiving the electrical input through the interconnecting-unit control line and thereby irreversibly electrically connect the first busbar and the second busbar.

Clause 5. The multilayered flexible interconnect circuit of clause 4, wherein the heating element is positioned between the first connecting portion and the second connecting portion.

Clause 6. The multilayered flexible interconnect circuit of clause 4, wherein the heating element is positioned either on an opposite side of the first connecting portion from the second connecting portion or on an opposite side of the second connecting portion from the first connecting portion.

Clause 7. The multilayered flexible interconnect circuit of clause 1, wherein: each one of the plurality of busbars comprises a first conductive layer and a second conductive layer, the contact portion is formed by both the first conductive layer and the second conductive layer, stacked in the contact portion, the first tab portion is formed by the first conductive layer such that the second conductive layer does not extend to the first tab portion, and the second tab portion is formed by the second conductive layer such that the first conductive layer does not extend to the second tab portion.

Clause 8. The multilayered flexible interconnect circuit of clause 7, wherein the first conductive layer and second conductive layer are separated from each other in the contact portion by an insulation layer.

Clause 9. The multilayered flexible interconnect circuit of clause 7, wherein the first conductive layer and second conductive layer directly interface each other in the contact portion.

Clause 10. The multilayered flexible interconnect circuit of clause 9, wherein the first conductive layer and the second conductive layer directly interface each other and are welded to one another in the contact portion.

Clause 11. The multilayered flexible interconnect circuit of clause 1, wherein at least one of the plurality of interconnecting units reversibly electrically connects the first tab portion and the second tab portion after receiving the electrical input.

Clause 12. The multilayered flexible interconnect circuit of clause 1, wherein at least one of the plurality of interconnecting units is connected to one of the plurality of busbars connected to a terminal of a battery and another one of the plurality of busbars connected to another terminal of the battery.

Clause 13. The multilayered flexible interconnect circuit of clause 1, wherein at least one of the plurality of interconnecting units is connected to one of the plurality of busbars connected to a terminal of a battery and another one of the plurality of busbars connected to another terminal of another battery.

Clause 14. The multilayered flexible interconnect circuit of clause 1, wherein each of the plurality of interconnecting units irreversibly electrically connects the first tab portion and the second tab portion after receiving the electrical input.

Clause 15. The multilayered flexible interconnect circuit of clause 1, wherein the electrical input has a voltage of 1-5 volts.

Clause 16. A battery assembly comprising: a plurality of busbars comprising a first busbar and a second busbar; a plurality of interconnecting units, each connected to two of the plurality of busbars and separately connected to an interconnecting-unit control line; a plurality of battery cells comprising cell terminals; and a battery management system, wherein: each of the plurality of busbars comprises a first conductive layer and a second conductive layer, each of the plurality of busbars is defined by a contact portion, a first tab portion, and a second tab portion, the contact portion is formed by both the first conductive layer and the second conductive layer, stacked in the contact portion, the first tab portion is formed by the first conductive layer such that the second conductive layer does not extend to the first tab portion, the second tab portion is formed by the second conductive layer such that the first conductive layer does not extend to the second tab portion, the cell terminals of each one of the plurality of battery cells are each electrically connected to different ones of the plurality of busbars, each of the interconnecting-unit control lines is electronically connected with the battery management system, the plurality of interconnecting units comprise an interconnecting unit stacked between and connected to each of the first tab portion of the first busbar and the second tab portion of the second busbar, each one of the plurality of interconnecting units maintains the two of the plurality of busbars electrically disconnected from each other before receiving an electrical input through the interconnecting-unit control line, and each one of the plurality of interconnecting units is configured to electrically connect the two of the plurality of busbars after receiving the electrical input through the interconnecting-unit control line.

Clause 17. The battery assembly of clause 16, further comprising a plurality of voltage traces, wherein each of the voltage traces electrically connects one of the plurality of busbars to the battery management system.

Clause 18. The battery assembly of clause 16, further comprising a battery management system power source electrically connected to the Battery Management System, wherein the battery management system power source is at least one of the plurality of battery cells.

Clause 19. A method of operating a battery assembly, the method comprising: providing a battery pack comprising: a plurality of busbars comprising a first busbar and a second busbar; a plurality of interconnecting units, each connected to two of the plurality of busbars and separately connected to an interconnecting-unit control line; a plurality of battery cells comprising cell terminals; a plurality of voltage traces; and a battery management system, wherein: each of the plurality of busbars comprises a first conductive layer and a second conductive layer, each of the plurality of busbars is defined by a contact portion, a first tab portion, and a second tab portion, the contact portion is formed by both the first conductive layer and the second conductive layer, stacked in the contact portion, the first tab portion is formed by the first conductive layer such that the second conductive layer does not extend to the first tab portion, the second tab portion is formed by the second conductive layer such that the first conductive layer does not extend to the second tab portion, the cell terminals of each one of the plurality of battery cells are each electrically connected to different ones of the plurality of busbars, each of the interconnecting-unit control lines is electronically connected with the battery management system, each of the voltage traces electrically connects one of the plurality of busbars to the battery management system, the battery management system is configured to determine SOH of each of the plurality of battery cells by measuring voltages at each of the plurality of busbars, the plurality of interconnecting units comprise an interconnecting unit stacked between and connected to each of the first tab portion of the first busbar and the second tab portion of the second busbar, each one of the plurality of interconnecting units maintains the two of the plurality of busbars electrically disconnected from each other before receiving an electrical input through the interconnecting-unit control line, and each one of the plurality of interconnecting units is configured to electrically connect the two of the plurality of busbars after receiving the electrical input through the interconnecting-unit control line; determining at the battery management system if the SOH of any one of the plurality of battery cells is unsatisfactory by comparing voltages measured at each of the plurality of busbars to a predetermined list of voltages; selecting at the battery management system which of the plurality of interconnecting units to provide an electrical input to; and providing, by the battery management system, an electrical input to the selected ones of the plurality of interconnecting units via at least one of the interconnecting-unit control line.

Clause 20. The method of operating a battery assembly of clause 19, the method further comprising: determining at the battery management system an SOC of any one of the plurality of battery cells with unsatisfactory SOH.

These and other embodiments are described further below with reference to the figures.

### BRIEF DESCRIPTION OF THE DRAWINGS

FIG. 1A is a top view of a portion of a multilayered flexible interconnect circuit illustrating an opening in the top (second) outer insulator and various boundaries of the conductive components, in accordance with some examples.

FIG. 1B is a schematic side view of two battery cells interconnected by the busbar of a multilayered flexible interconnect circuit, in accordance with some examples.

FIG. 1C is a cross-sectional side view of a multilayered flexible interconnect circuit identifying various components and portions of the circuit, in accordance with some examples.

FIG. 1D is an expanded cross-sectional side view of the busbar support portion of the multilayered flexible interconnect circuit in FIG. 2B, in accordance with some examples.

FIG. 2A is a top view of a portion of a multilayered flexible interconnect circuit illustrating an arrangement of busbars and interconnecting units, in accordance with some examples.

FIG. 2B is a top view of a busbar formed from two conductive layers illustrating the contact portion, first tab portion, and second tab portion, in accordance with some examples.

FIG. 2C is a side view of the busbar shown in FIG. 2B, in accordance with some examples.

FIG. 2D is a side view of an interconnecting unit in contact with a first busbar and a second busbar, in accordance with some examples.

FIG. 2E is a side view of an interconnecting unit in contact with a first busbar and a second busbar, in accordance with some examples.

FIG. 2F is a side view of an interconnecting unit in contact with a first busbar and a second busbar, in accordance with some examples.

FIG. 2G is a top view of a portion of a multilayered flexible interconnect circuit comprising a plurality of busbars and connected components, in accordance with some examples.

FIG. 3A is a schematic view of an interconnecting unit connecting a first busbar and a second busbar, illustrating the flow of electricity through the battery when no electrical input is received at the interconnecting-unit control line, in accordance with some examples.

FIG. 3B is a schematic view of an interconnecting unit connecting a first busbar and a second busbar, illustrating the flow of electricity through the interconnecting unit when an electrical input is received at the interconnecting-unit control line, in accordance with some examples.

FIG. 4A is a schematic block diagram illustrating the relationships of components general to interconnecting units, in accordance with some examples.

FIG. 4B is a schematic block diagram illustrating the relationships of components specific to an interconnecting unit comprising a transistor, in accordance with some examples.

FIG. 4C is a schematic block diagram illustrating the relationships of components specific to an interconnecting unit comprising a normally-open relay, in accordance with some examples.

FIG. 4D is a schematic block diagram illustrating the relationships of components specific to a heat-actuated interconnecting unit, in accordance with some examples.

FIG. 5 is a schematic block diagram illustrating the relationships of components of battery assemblies comprising interconnecting units, in accordance with some examples.

FIG. 6 is a process flowchart corresponding to a method of fabricating a multilayered flexible interconnect circuit, in accordance with some examples.

FIG. 7 is a process flowchart corresponding to a method of operating battery packs comprising multilayered flexible interconnect circuits with a plurality of interconnecting units.

### DETAILED DESCRIPTION

In the following description, numerous specific details are outlined to provide a thorough understanding of the presented concepts. In some examples, the presented concepts are practiced without some or all of these specific details. In other examples, well-known process operations have not been described in detail to unnecessarily obscure the described concepts. While some concepts will be described in conjunction with specific examples, it will be understood that these examples are not intended to be limiting.

### Introduction

As noted above, conventional busbars used for connecting battery cells are typically used as individual components stamped from thick metal sheets to ensure sufficient current capabilities. However, this individual component aspect complicates the battery pack assembly process, e.g., requiring individual handling and alignment of each component. Furthermore, these thick metal sheets may not be sufficiently flexible to accommodate various alignment deviations among battery cells, which further complicates the installation process. Finally, various additional components (besides battery cells, e.g., voltage-sense harnesses) need to be connected to busbars adding even more operational complexities.

Battery packs are collections of electrically connected battery cells. Each individual battery cell in the battery pack typically does not provide sufficient voltage or energy storage capacity to sufficiently power, for example, an electric vehicle. To achieve sufficient voltage to operate electric motors in, for example, electric vehicles, sets of batteries are often connected in series using busbars. Busbars connect the negative terminal of one battery cell to the positive terminal of an adjacent battery cell. In order to supply sufficient current, multiple series of battery cells may be connected with one another in parallel. Battery modules/packs may comprise more than 50 battery cells or even more than 100 battery cells in some designs (e.g., 800V battery packs).

A battery cell in a battery pack may fail in one of at least two failure modes during charging operations or operation of the vehicle. One possible failure mode is when the damaged battery cell acts as an open circuit between the two terminals. When one battery cell in a series fails in a failure mode resulting in an open circuit, the entire series will no longer provide power to the electric vehicle. The battery pack may then be unable to provide sufficient power for operation of the vehicle.

If the failure mode results in a short between the terminals of one battery cell, the result may be a rapid discharge of the failed battery. Rapid discharging may result in generation of significant heat energy at the location of the battery cell. This heat generation may trigger failure of adjacent battery cells, which may also generate heat and damage further battery cells, resulting in a so-called thermal runaway event.

For some electric vehicles, it would be desirable to have a Limp-home mode available in case of failure of one or more battery cells. A limp-home mode may enable continued operation of an electric vehicle in case of a battery cell failure. A battery management system (BMS) may disconnect individual batteries from the rest of the battery pack. It may then route power from the remaining connected battery cells to allow safe operation of the vehicle but for a limited range. This may, for example, allow operation of the vehicle to a safe stopping location. It may provide sufficient power for the battery management system to continue to measure and manage the battery pack in a safe state. This may provide passengers the opportunity to park the vehicle and exit safely. It may, for example, allow operation of the vehicle to a location where the vehicle can be repaired. It may be desirable for a battery pack of a disabled vehicle to continue to provide some power for operating accessories. For example, in cold environments, it may be desirable for a disabled vehicle to operate passenger cabin heaters. Electric tractors may often be operated far from roads and repair infrastructure. It may be desirable for electric tractors to provide a limp-home mode in case of battery cell failure. In some cases, local regulations may require that an electric vehicle is equipped to provide a limp-home mode. In the case of electric aircraft powered by battery packs, it may be desirable for a limp-home mode to provide sufficient power for the vehicle to be safely landed on the ground.

In each of these applications, a battery management system may be used to both sense battery cell failure and change connections between individual battery cells. For some applications, it may be desirable to power a battery management system (BMS) with a secondary battery power source. This secondary battery power source may be, for example, a 12 V or 48 V battery pack with smaller power storage capacity than the primary battery pack. This would provide power to the BMS to continue to monitor the health of battery cells in the primary battery pack even if, after failure of one or more battery cells, the battery pack is disconnected from its primary load. However, the battery management system may itself require electrical power to continue operation. The electrical power may be provided by a backup battery system. For example, an auxiliary 12 volt or 48 volt battery pack may be provided separately to the primary battery pack. However, to reduce cost, mass, and space required to include a separate battery pack, it may be desirable to operate the BMS from the primary battery pack. In this arrangement, disconnecting the entire battery pack from powering systems of the electric vehicle in case of a battery cell failure may not be desirable. Instead, it would be desirable to disconnect a selection of batteries to allow, for example, providing continuous power to the BMS. This would require dynamic electrical connections between battery cells.

For continued operation of the vehicle and for enhanced operator safety in cases of battery cell failure, it would be desirable to limit the negative consequences of both cell failure modes on the battery pack. However, existing battery packs electrically connect batteries via static connections to busbars.

Multilayered flexible interconnect circuits described herein address various issues listed above. Specifically, a multilayered flexible interconnect circuit comprises at least two conductive layers and at least one inner insulator, which extends between these conductive layers in some circuit portions and allows conductive layers to directly interface in other circuit portions (e.g., busbar portions). In other words, when high current-carrying capabilities are needed, multiple conductive layers (e.g., all conductive layers) are in that portion of the circuit. It should be noted that stacking multiple conductive layers increases the flexibility of this stack in comparison to a monolithic component with the same thickness (and the same current-carrying capability). Alternatively, when only low current-carrying capabilities are needed (e.g., for voltage sensing), fewer than all conductive layers (e.g., only one conductive layer) can be used in this circuit portion. Since all components of the same conductive layer are formed from the same initial metal sheet, these components may be monolithically integrated (and do not require any later connections). Furthermore, components of different conductive layers may directly interface with each other (e.g., through an opening within an inner insulator layer) and even welded to each other (e.g., through an opening within an outer insulator layer). In some examples, the components of different conductive layers may be welded to each other while welding these to various external components (e.g., battery terminals). It should be noted that one or more inner insulators allow stacking multiple conductive layers while forming electrical connections between these layers, e.g., having multiple voltage traces crossing over.

The multilayered flexible interconnect circuit comprises a plurality of busbars connecting terminals of battery cells. The multilayered flexible interconnect circuit also comprises a plurality of interconnecting units. Each interconnecting unit is connected to two of the plurality of busbars and is separately connected to an interconnecting-unit control line. Each interconnecting unit is configured to maintain the two busbars to which is connected electrically disconnected unless it receives an electrical input. Each layer interconnecting unit is configured to electrically connect the two busbars upon receiving an electrical input. Electrically connecting the two busbars changes the electrical connections among the plurality of battery cells. Electrically connecting the two busbars removes one or more battery cells from a series of battery cells while conducting electricity around the removed cells. Layer interconnecting units may comprise connected components in addition to the multilayered flexible interconnect circuit. Multiple conductive layers may be where leads for carrying current from busbars to layer interconnecting units are. Conductor layers connecting busbars to layer interconnecting units are on different conductive layers. Conductor layers connecting busbars to layer interconnecting units may have at least one insulator layer positioned between. Interconnecting-unit control lines are included in the multilayered flexible interconnect circuit. Interconnecting-unit control lines may be included on conductive layers. Interconnecting-unit control lines may, for example, carry electrical signals from the BMS to layer interconnecting units. Examples of layer interconnecting units are described in more detail below.

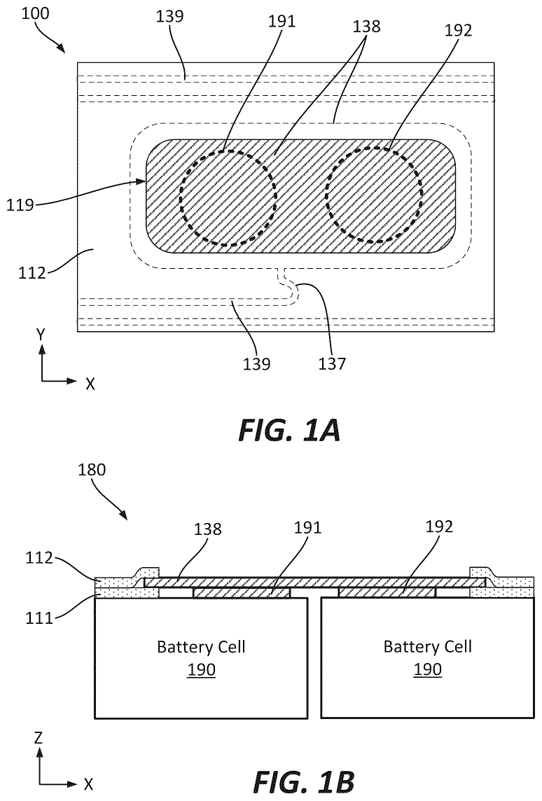

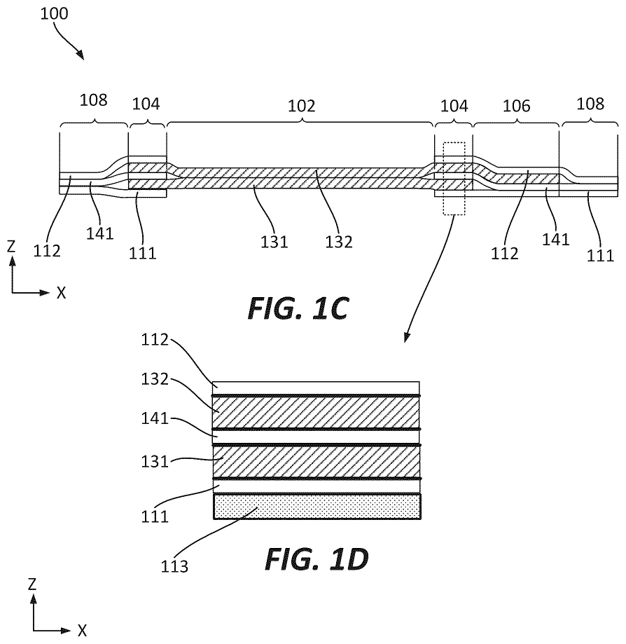

### FIGS. 1A-1B: Examples of Multilayered Flexible Interconnect Circuit Assemblies

The functional and structural aspects of multilayered flexible interconnect circuits will now be described in the context of FIGS. 1A-1D. Specifically, FIG. 1A is an expanded top view of a portion of a multilayered flexible interconnect circuit illustrating openings 119 in the second outer insulator layer 112 and the boundaries of conductive components, in accordance with some examples. Specifically, a portion of the busbar 138 may overlap with the second outer insulator layer 112 (and, e.g., a first outer insulator layer 111 as shown in FIG. 1B) to support the busbar 138 within the multilayered flexible interconnect circuit 100. Furthermore, FIG. 1A illustrates a voltage trace 139 extending to the busbar 138 (and being monolithic with one of the conductive layers forming the busbar 138). A portion of the voltage trace 139 can be specifically shaped and referred to as a voltage trace connection portion 137. The voltage trace connection portion 137 may interconnect a linear portion of the voltage trace 139 and busbar 138 and allow for the out-plane movement of the busbar 138 relative to the linear portion of the voltage trace 139 while preserving this monolithic connection. FIG. 1A also illustrates additional voltage trace 139 extending next to each other (e.g., to other busbars). As noted above, additional voltage traces can be offset along the Z-axis. Each conductive component is formed by one or more conductive layers.

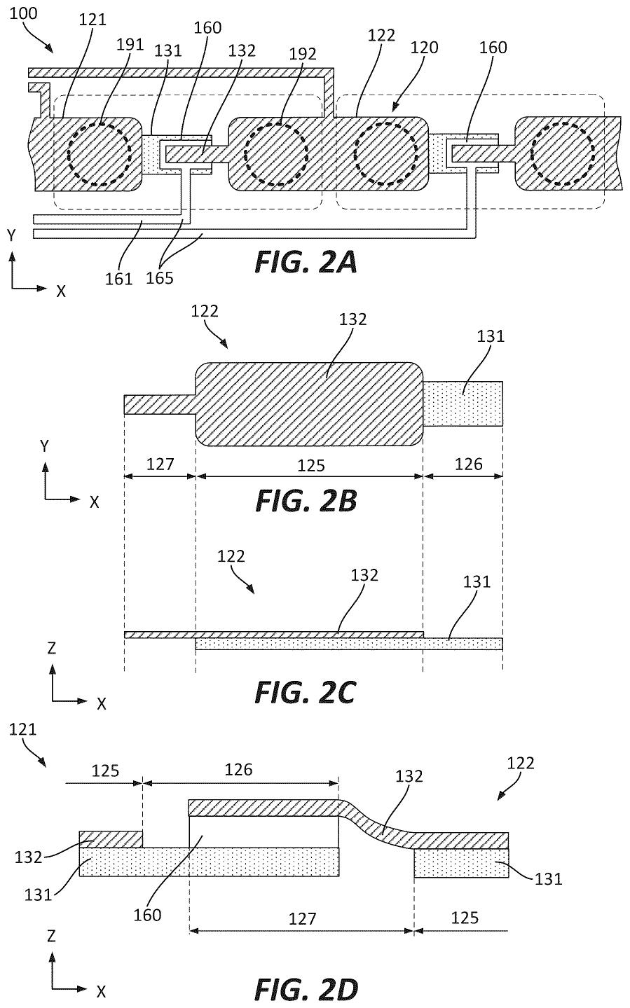

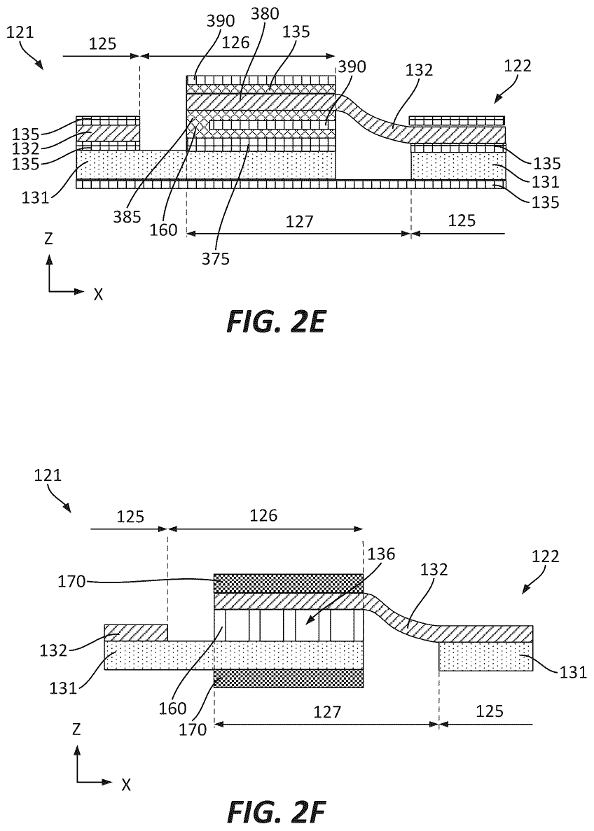

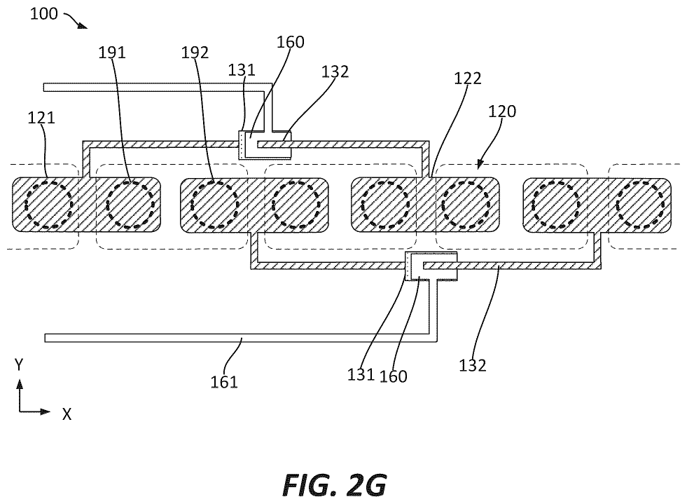

FIG. 1B is a side view of battery cells 190 forming a battery assembly 180, in accordance with some examples. In FIG. 1B, the battery cells 190 are prismatic cells, but other types of cells are within the scope. In the illustrated example, the set includes two battery cells. However, any other number and/or arrangements of battery cells are within the scope. Each battery cell 190 comprises cell terminals 191 and 192, such as a positive cell tab and a negative cell tab. In the illustrated example, both cell terminals 191 and 192 are positioned on the same side of battery cell 190. However, other examples (e.g., with cell terminals being positioned on opposite sides of battery cells 190) are also within the scope. In these examples, multiple multilayered flexible interconnect circuits may be used to interconnect the same set of battery cells 190. The cell terminals 191 and 192 are used for interconnecting the battery cells 190, e.g., with all cells being interconnected in series as further shown with the design of the multilayered flexible interconnect circuit 100 presented in FIG. 2A. However, other connection schemes (e.g., parallel and various combinations of parallel and in-series connections) are also within the scope.

The number of the conductive layers forming each component depends on the current carrying requirement of these specific components. Specifically, these conductive components may include busbars 138 and voltage traces 139. Busbars 138 are examples of high-current-carrying conductive components, each formed using multiple conductive layers of the multilayered flexible interconnect circuit 100. Busbars 138 are connected (e.g., welded) to the cell terminals 191 and 192 during the fabrication of a battery assembly 180 (e.g., a battery pack). It should be noted that during this fabrication operation, all busbars 138 are integrated and supported within the multilayered flexible interconnect circuit 100 thereby eliminating the need to handle and align each busbar (in comparison to conventional methods).

Voltage traces 139 are examples of low-current carrying conductive components, each formed using fewer than all conductive layers of the multilayered flexible interconnect circuit 100 (e.g., only one conductive layer for each voltage trace). However, having multiple conductive layers allows routing/stacking multiple voltage traces 139 in the same portion of the multilayered flexible interconnect circuit 100. Furthermore, precise patterning of each conductive layer allows the positioning of multiple voltage traces 139 side-by-side. Voltage traces 139 can be connected to each of the busbars 138 and some form of controller (e.g., a battery management system). More specifically, a voltage trace 139 can be monolithic with one or more busbars 138 or, more specifically, with a portion of the conductive layer that both forms this voltage trace 139 and a portion of the busbar. In some examples, a battery management system is a part of a multilayered flexible interconnect circuit 100. Alternatively, the busbar portion 102 can be connected to the multilayered flexible interconnect circuit 100 or, more specifically, to the voltage traces 139 of the multilayered flexible interconnect circuit 100 during the fabrication of a battery assembly 180 (e.g., a battery pack).

Overall, a multilayered flexible interconnect circuit 100 comprises multiple conductive layers stacked along the Z-direction as further described below with reference to FIGS. 1C-1D. Some conductive components (e.g., high-current carrying components such as busbars 138) may be formed using all or at least two or more conductive layers. Other conductive components (e.g., low-current carrying components such as voltage traces 139) may be formed using a single conductive layer or at least fewer than all conductive layers.

### FIGS. 1C-1D: Examples of Different Portions of Multilayered Flexible Interconnect Circuits

FIG. 1C is a cross-sectional side view of a multilayered flexible interconnect circuit 100, in accordance with some examples. The multilayered flexible interconnect circuit 100 comprises a first outer insulator layer 111, a second outer insulator layer 112, an inner insulator layer 141, a first conductive layer 131, and a second conductive layer 132. As noted above, the multilayered flexible interconnect circuit 100 comprises at least two conductive layers, e.g., a first conductive layer 131 and a second conductive layer 132. However, any number of conductive layers are within the scope. In some examples, a multilayered flexible interconnect circuit 100 comprises four, five, six, or even more conductive layers.

Referring to FIG. 1C, the first outer insulator layer 111, second outer insulator layer 112, inner insulator layer 141, first conductive layer 131, and second conductive layer 132 collectively define a busbar portion 102, a busbar support portion 104, and a metal-free portion 108 of the multilayered flexible interconnect circuit 100. In some examples, these components also define an insulated conductor portion 106 of the multilayered flexible interconnect circuit 100. The structure and function of each of these portions will now be described in more detail. These portions may have different combinations of the first outer insulator layer 111, second outer insulator layer 112, inner insulator layer 141, first conductive layer 131, and second conductive layer 132 thereby forming different components of the multilayered flexible interconnect circuit 100. For example, a combination of the busbar portion 102 and busbar support portion 104 forms a busbar 138. More specifically, the busbar portion 102 represents the exposed portion of the busbar 138 allowing various connections to the busbar. The busbar support portion 104 provides the mechanical support to the busbar portion 102.

Referring to FIG. 1C, in the busbar portion 102, the first conductive layer 131 and the second conductive layer 132 directly interface with each other. In other words, the inner insulator layer 141 is not a part of the busbar portion 102 or, more specifically, the inner insulator layer 141 has an opening that coincides with the busbar portion 102. The interfacing allows direct interconnection of the first conductive layer 131 and the second conductive layer 132 (e.g., by welding).

Furthermore, the surface of the first conductive layer 131 facing away from the second conductive layer 132 is exposed, e.g., to form a direct connection to cell terminals 192. This exposure is provided by an opening in the first outer insulator layer 111. Similarly, the surface of the second conductive layer 132 facing away from the first conductive layer 131 is exposed, e.g., to allow for welding or other tools to reach the second conductive layer 132 such as while forming a connection to cell terminals 192. This exposure is provided by an opening in the second outer insulator layer 112. For example, in a battery assembly, the first conductive layer 131 may be positioned between the second conductive layer 132 and cell terminals 192. The welding of the first conductive layer 131 to the cell terminals 192 may be performed through the second conductive layer 132 such that this welding also interconnects the first conductive layer 131 and second conductive layer 132. Stacking and interconnecting the first conductive layer 131 and second conductive layer 132 allows a higher current between the cell terminals 192 connected to these conductive layers. In some examples, the busbar portion 102 provides a current rating of at least 50 Amperes, at least 100 Amperes, or even at least 200 Amperes. In the same or other examples, the collective thickness of all conductive layers forming the busbar portion 102 is at least 200 micrometers, at least 500 micrometers, at least 1 millimeter, or even at least 3 millimeters. This combined thickness depends on the (1) required current ratings, (2) one or more materials of the conductive layers, (3) the thickness of each layer, and (4) the number of layers. It should be noted that separating this thickness into multiple layers allows use different footprints/patterns for each conductive layer thereby monolithically integrating different features into one or more conductive layers.

To form a busbar portion 102, an opening is formed in each of the first outer insulator layer 111, second outer insulator layer 112, and inner insulator layer 141. In other words, each of the first outer insulator layer 111, second outer insulator layer 112, and inner insulator layer 141 has an opening in the busbar portion 102. The opening in the inner insulator layer 141 allows the first conductive layer 131 and the second conductive layer 132 to directly interface with each other. The opening in the first outer insulator layer 111 provides access and exposes a portion of the first conductive layer 131, e.g., to form connections to cell terminals 192. The opening in the second outer insulator layer 112 provides access and exposes a portion of the second conductive layer 132, e.g., during welding of the second conductive layer 132 to the first conductive layer 131 and to the cell terminals 192.

Referring to FIG. 1C, in some examples, the busbar support portion 104 can partially surround and support the busbar portion 102. Specifically, before being connected to cell terminal 192, different conductive layers are not interconnected or otherwise attached in the busbar portion 102. In other words, before being connected to cell terminals 192, the busbar portion 102 is a stack of multiple conductive layers that directly interface with each other but are not connected in the busbar portion 102. This connection is provided by the insulator layers in the busbar portion 102. Specifically, in the busbar support portion 104, the inner insulator layer 141 is stacked between and directly interfaces the first conductive layer 131 and the second conductive layer 132, e.g., as shown in FIGS. 1C and 1D. More specifically, the inner insulator layer 141 is bonded to and supports both the first conductive layer 131 and the second conductive layer 132. Furthermore, in the busbar support portion 104, the first conductive layer 131 is stacked between and directly interfaces the first outer insulator layer 111 and the inner insulator layer 141. The first conductive layer 131 can be bonded to and supported by both the first outer insulator layer 111 and the inner insulator layer 141. Finally, in the busbar support portion 104, the second conductive layer 132 is stacked between and directly interfaces the inner insulator layer 141 and the second outer insulator layer 112. Again, the second conductive layer 132 can be bonded and supported by both the inner insulator layer 141 and the second outer insulator layer 112. Overall, all three of the inner insulator layer 141, the first outer insulator layer 111, and the second outer insulator layer 112 can be used to support the first conductive layer 131 and second conductive layer 132 relative to each other and other components in the multilayered flexible interconnect circuit 100, at least in the busbar support portion 104.

In some examples, at least one of the first outer insulator layer 111 or the second outer insulator layer 112 or even both the first outer insulator layer 111 and the second outer insulator layer 112 are not present in the busbar support portion 104 thereby exposing one or both of the first conductive layer 131 and second conductive layer 132. The support to the first conductive layer 131 and the second conductive layer 132 can be provided by at least the inner insulator layer 141.

Referring to FIG. 1C, in some examples, in the metal-free portion 108, the inner insulator layer 141 is stacked between and directly interfaces the first outer insulator layer 111 and the second outer insulator layer 112. The metal-free portion 108 may be used for supporting different insulators relative to each other in the multilayered flexible interconnect circuit 100. Alternatively, the metal-free portion 108 is formed by the first outer insulator layer 111 and the second outer insulator layer 112 but not by the inner insulator layer 141 (i.e., the inner insulator layer 141 may not extend through the metal-free portion 108). Furthermore, in some examples, the metal-free portion 108 may be formed by the inner insulator layer 141 and only one or the first outer insulator layer 111 and the second outer insulator layer 112. The metal-free portion 108 can form at least some of the outside edges of the multilayered flexible interconnect circuit 100 (e.g., to position and seal the first conductive layer 131 and second conductive layer 132 away from these edges). In some examples, all conductive layers of the multilayered flexible interconnect circuit 100 are positioned away from the edges of the multilayered flexible interconnect circuit 100. In this example, the connections to the conductive layers may be formed through various openings in the insulators. Alternatively, at least a portion of the first conductive layer 131 and/or second conductive layer 132 may extend through one or more edges of the multilayered flexible interconnect circuit 100.

Referring to FIG. 1C, in some examples, the multilayered flexible interconnect circuit 100 comprises an insulated conductor portion 106. Unlike the busbar support portion 104, which comprises multiple conductive layers (e.g., all conductive layers forming the adjacent the busbar portion 102), an insulated conductor portion 106 can include fewer than all conductive layers, such as only one conductive layer, e.g., a second conductive layer 132 as shown in FIG. 1C. Specifically, in the insulated conductor portion 106, the second conductive layer 132 is stacked between and directly interfaces the inner insulator layer 141 and the second outer insulator layer 112. The inner insulator layer 141 is stacked between and directly interfaces the second conductive layer 132 and the first outer insulator layer 111. Referring to FIG. 1C, in some examples, the insulated conductor portion 106 is positioned between the busbar support portion 104 and metal-free portion 108. In the same or other examples, the busbar support portion 104 is positioned between the busbar portion 102 and the metal-free portion 108.

In some examples, each of the first outer insulator layer 111, the second outer insulator layer 112, the inner insulator layer 141, the first conductive layer 131, and the second conductive layer 132 is formed from the same starting sheet. As such, each of the first outer insulator layer 111, the second outer insulator layer 112, the inner insulator layer 141, the first conductive layer 131, and the second conductive layer 132 may have the same thickness and composition throughout the entire footprint of the multilayered flexible interconnect circuit 100. In fact, some layers (e.g., the first outer insulator layer 111 and/or the second outer insulator layer 112) may be monolithic throughout the entire footprint of the multilayered flexible interconnect circuit 100. Other layers may be cut into disjoined components, e.g., busbars, insulating patches, etc. It should be noted that each layer is individually patterned to form different portions/components of the multilayered flexible interconnect circuit 100.

Referring to FIG. 1D, in some examples, each of the first outer insulator layer 111 and the second outer insulator layer 112 comprises a polymer base and an adhesive layer covering a surface of and supported by the polymer base. The polymer base comprises one or more polymer selected from the group consisting of polyimide (PI), polyethylene naphthalate (PEN), polyethylene terephthalate (PET), polymethyl methacrylate (PMMA), ethyl vinyl acetate (EVA), polyethylene (PE), polyvinyl fluoride (PVF), polyamide (PA), and/or polyvinyl butyral (PVB). The adhesive layer comprises one or more of epoxy and polyurethane. In more specific examples, in the busbar support portion 104, the adhesive layer of the first outer insulator layer 111 directly interfaces and is adhered to the first conductive layer 131. The adhesive layer of the second outer insulator layer 112 directly interfaces and is adhered to the second conductive layer 132.

Referring to FIG. 1D, in some examples, the inner insulator layer 141 comprises an inner polymer base, a first inner adhesive layer, and a second inner adhesive layer. The inner polymer base is positioned between and supports each of the first inner adhesive layer and the second inner adhesive layer. The inner polymer base comprises one or more polymer selected from the group consisting of polyimide (PI), polyethylene naphthalate (PEN), polyethylene terephthalate (PET), polymethyl methacrylate (PMMA), ethyl vinyl acetate (EVA), polyethylene (PE), polyvinyl fluoride (PVF), polyamide (PA), and/or polyvinyl butyral (PVB). Each of the first inner adhesive layer and the second inner adhesive layer comprises one or more of epoxy and polyurethane. In more specific examples, in the busbar support portion 104, the first inner adhesive layer of the inner insulator layer 141 directly interfaces and is adhered to the first conductive layer 131. Furthermore, the adhesive layer of the second outer insulator layer 112 directly interfaces and is adhered to the second conductive layer 132.

In some examples, each of the first conductive layer 131 and the second conductive layer 132 comprises aluminum. However, other metals (e.g., copper) are also within the scope. In some examples, all conductive layers (e.g., both the first conductive layer 131 and the second conductive layer 132) are formed from the same material, e.g., aluminum, copper, or the like. Alternatively, different metals may be used for the first conductive layer 131 and the second conductive layer 132. In general, the first conductive layer 131 and the second conductive layer 132 may be formed from any conductive material that is sufficiently conductive (e.g., a conductivity being greater than 10\hat{ }6 S/m or even greater than 10\hat{ }7 S/m to allow for current flow through the foil with low power loss.

In some examples, each of the first conductive layer 131 and the second conductive layer 132 has a thickness of 100-400 micrometers or, more specifically, 200-300 micrometers. The total thickness of all conductive layers forming a busbar can be at least 400 micrometers, at least 600 micrometers, at least 800 micrometers, or even at least 1,000 micrometers such as 500-2,000 micrometers or, more specifically, 600-1,200 micrometers.

This thickness depends on the current-carrying requirements from the busbar. In some examples, all conductive layers in a multilayered flexible interconnect circuit 100 have the same thickness, e.g., as shown in FIG. 1D. Alternatively, at least one conductive layer is thicker than another conductive layer in the multilayered flexible interconnect circuit 100.

Referring to FIG. 1D, in some examples, a multilayered flexible interconnect circuit 100 further comprises a circuit bonding layer 113, e.g., a double-sides pressure sensitive adhesive (PSA) layer.

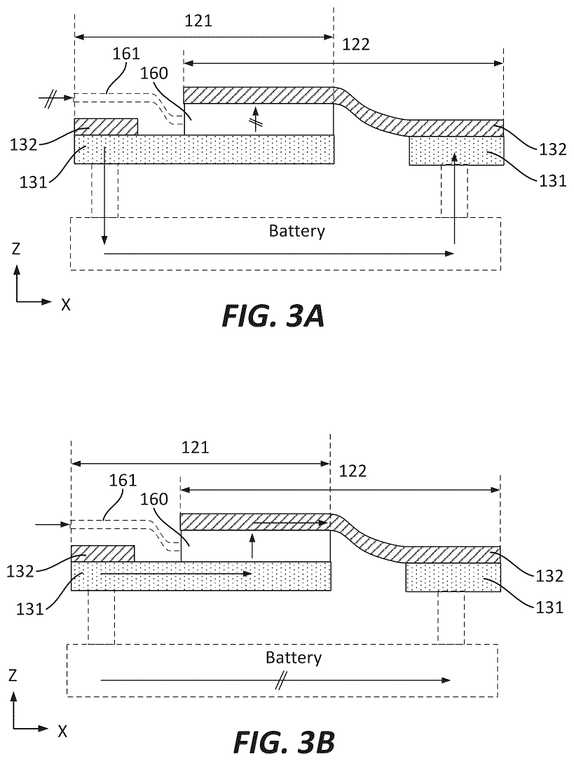

### FIGS. 2A-3B: Examples of Multilayered Flexible Interconnect Circuits Comprising Interconnecting Units

The functional and structural aspects of multilayered flexible interconnect circuits comprising interconnecting units will now be described in the context of FIGS. 2A-2F. Specifically, FIG. 2A is an expanded top view of a portion of a multilayered flexible interconnect circuit comprising a plurality of busbars 120 and connected components, in accordance with some examples. The multilayered flexible interconnect circuit 100 comprises a plurality of busbars 120, a plurality of interconnecting-unit control lines 165, and a plurality of interconnecting units 160. Each one of the plurality of busbars 120 is defined by a contact portion 125, a first tab portion 126, and a second tab portion 127. The plurality of interconnecting-unit control lines 165 comprises more than one interconnecting-unit control line 161. Each one of the plurality of interconnecting units 160 is connected to two of the plurality of busbars 120 and is separately connected to an interconnecting-unit control line 161. Each one of the plurality of interconnecting units 160 is stacked between and connected to the first tab portion 126 of one of the plurality of busbars 120 and the second tab portion 127 of another one of the plurality of busbars 120. In some examples, at least one of the plurality of interconnecting units 160 is stacked between either a first tab portion 126 or a second tab portion 127 of one of the plurality of busbars 120 and the other of either a first tab portion 126 and a second tab portion 127 of the another one of the plurality of busbars 120. In some further examples one of the plurality of busbars 120 is a first busbar 121 and the other one of the plurality of busbars 120 is a second busbar 122.

Each one of the plurality of interconnecting units 160 electrically disconnects the first tab portion 126 first tab portion 126 and the second tab portion 127 before receiving an electrical input through the interconnecting-unit control line 161. In other words, when any one of the plurality of interconnecting units 160 does not receive an electrical input via the interconnecting-unit control line 161, the first tab portion 126 and the second tab portion 127 are electrically disconnected. When one of the plurality of interconnecting units 160 receives an electrical input through the interconnecting-unit control line 161, the plurality of interconnecting units 160 electrically connects the first tab portion 126 and the second tab portion 127 it is connected with. Each one of the plurality of interconnecting units 160 is configured to electrically connect the two of the plurality of busbars 120 it is connected to after receiving the electrical input through the interconnecting-unit control line 161 it is connected to.

In some examples, the plurality of busbars 120 comprises a first busbar 121 and a second busbar 122. Each one of the plurality of busbars 120 comprises a first conductive layer 131 and a second conductive layer 132. In some examples, the first tab portion 126 is formed from the first conductive layer 131 and the second tab portion 127 is formed from the second conductive layer 132. In these examples, this may provide manufacturing benefits. For example, it may simplify manufacturing of the multilayered flexible interconnect circuit 100 if the plurality of interconnecting units 160 can be placed between conductive layers used to form the first conductive layer 131 and second conductive layer 132.

As described above, each one of the plurality of interconnecting units 160 is physically connected to two of the plurality of busbars 120 but maintains the two of the plurality of busbars 120 in electrical disconnection before receiving an electrical input through the interconnecting-unit control line 161. Shown in FIG. 3A is a schematic cross-sectional side view of one of the plurality of interconnecting units 160 connecting a first busbar 121 and a second busbar 122. Shown are a first conductive layer 131 and a second conductive layer 132 from a first busbar 121 and a first conductive layer 131 and a second conductive layer 132 from a second busbar 122. Also shown is the interconnecting-unit control line 161 connected to the one of the plurality of interconnecting units 160. The first busbar 121 is connected to a terminal of a battery cell and the second busbar 122 is connected to another terminal of the same battery cell. In FIG. 3A, no electrical input is received via the interconnecting-unit control line 161. The one of the plurality of interconnecting units 160 is configured to maintain electrical disconnection between the first busbar 121 and the second busbar 122. Electrical current flows from the first busbar 121 into and through the battery cell and into the second busbar 122.

The first busbar electrically connects cell terminal 192 (not shown) of a battery cell (not shown) to cell terminal 191 of another battery cell. Second busbar 122 electrically connects cell terminal 192 to cell terminal 191 of yet another battery cell. The plurality of busbars 120 connects the adjacent battery cells shown in FIG. 2A in series. Other arrangements in which some of the plurality of busbars 120 connect battery cells or series sets of battery cells in parallel are also within the scope. Shown in FIGS. 2B and 2C are expanded top view (2B) and expanded side view (2C) of second busbar 122. As shown for second busbar 122, The contact portion 125 is formed by both the first conductive layer 131 and the second conductive layer 132, stacked in the contact portion 125. The first tab portion 126 is formed by the first conductive layer 131 such that the second conductive layer 132 does not extend to the first tab portion 126. The second tab portion 127 is formed by the second conductive layer 132 such that the first conductive layer 131 does not extend to the second tab portion 127.

FIG. 2G is an expanded top view of a portion of a multilayered flexible interconnect circuit comprising a plurality of busbars 120 and connected components, in accordance with some examples. In FIG. 2A, the plurality of interconnecting units 160 are placed between the first conductive layer 131 and second conductive layer 132 of individuals of the plurality of busbars 120 attached to separate terminals of the same battery cells 190. In FIG. 2G, the plurality of interconnecting units 160 are placed between the first conductive layer 131 and second conductive layer 132 of busbars that are attached to terminals of separate battery cells 190. In this configuration, electrically connecting the first conductive layer 131 and the second conductive layer 132 allows current to flow around a disabled battery cell and an adjacent battery cell. As shown in FIG. 2G, in these examples, a portion of the first conductive layer 131 and a portion of the second conductive layer 132 may extend to form a path, with one of the plurality of interconnecting units 160, around one or more other busbars.

Where the configuration of interconnecting units 160 and plurality of busbars 120 shown in FIG. 2A will form an electrical short pathway between the two terminals of a battery cell 190, the configuration in shown in FIG. 2G will not form an electrical short pathway between the terminals of a battery cell 190. This may provide a benefit in situations where a battery cell 190 has failed and is charged to a high state of charge. In such a situation, creating a short pathway between the two terminals of a battery cell 190 may be desirable if the battery cell 190 has failed in a mode forming an open circuit between the terminals of the two battery cells 190. However, creating a short pathway between the two terminals of a battery cell 190 may be dangerous if the battery cell 190 has failed in another way. A battery cell 190 may rapidly discharge its stored electrical energy through the electrical connection formed between the first conductive layer 131 and the second conductive layer 132. This may create a dangerous temperature increase due to resistive heating of the electrical short pathway. Instead, passing the electrical current from the rest of the interconnected battery cells 190 around the damaged battery cell and an adjacent battery cell 190 may be desirable. Importantly, a multilayered flexible interconnect circuit 100 may comprise both the configuration shown in FIG. 2A and the configuration shown in

FIG. 2G. This may be a benefit provided by the construction the multilayered flexible interconnect circuit 100. For example, if the plurality of busbars 120 are formed from four conductive layers, two layers may be used to form a first conductive layer 131 and a second conductive layer 132 configured to connect a first busbar 121 and a second busbar 122 that are adjacent. Two other layers may be used to form a first conductive layer 131 and a second conductive layer 132 configured to connect a first busbar 121 and a second busbar 122 that are not adjacent.

Each of the plurality of interconnecting units 160 is configured to electrically connect the two of the plurality of busbars 120 after receiving the electrical input. FIG. 3B is a schematic view of one of the plurality of interconnecting units 160 connecting a first busbar 121 and a second busbar 122, after an electrical input is received via the interconnecting-unit control line 161. In this example, the one of the plurality of interconnecting units 160 is configured to electrically connect the first busbar 121 and second busbar 122. Electrical current flows from the first busbar 121 to the second busbar 122 and does not flow through the battery cell. Details of configurations of the plurality of interconnecting units 160 will be described in more detail below. In some examples, the electrical input has a magnitude of 0.25-12 Volts, 0.5-9 Volts, or even 1-5 Volts.

In some examples, the first conductive layer 131 and second conductive layer 132 are directly interfacing each other in the contact portion 125, as shown in FIG. 2D. In other examples, the first conductive layer 131 and second conductive layer 132 are separated from each other in the contact portion 125 by an insulation layer 135, as shown in FIG. 2E.

In some examples, the interconnecting-unit control line 161 is a dedicated trace, separate from any other conductor traces, for example, a voltage trace 139. In other examples, the interconnecting-unit control line 161 is a voltage trace 139. In some examples, one interconnecting-unit control line 161 is connected to more than one of the plurality of interconnecting units 160. In these examples, an electrical signal transmitted by the interconnecting-unit control line 161 can control more than one of the plurality of interconnecting units 160 at once. In other examples, at least one of the plurality of interconnecting units 160 is connected to more than one interconnecting-unit control line 161. In these examples, electrical signals may be transmitted separately by more than one interconnecting-unit control line 161 to one of the plurality of interconnecting units 160.

In some examples, the plurality of busbars 120 may be positioned such that they are suspended above the surface of the battery cells 190 where the cell terminals 191 and cell terminals 192 are positioned. The insulator layers of the multilayered flexible interconnect circuit 100 may have a vaporization point lower than temperatures expected to exist near the surface of a battery cell 190 undergoing thermal run-away. In these examples, the plurality of interconnecting units 160 is located either close to the surface of the battery cell 190 or directly over a cell vent. A cell vent is a pressure release valve built into the container of a battery cell 190 to release hot metal and gases in the event of a thermal run-away. The high temperatures of either the surface of the battery cell 190 or escaping from a cell vent will melt and vaporize the insulator layers, allowing the first conductive layer 131 and second conductive layer 132 to make electrical contact. This can provide protection to the battery assembly 180 by removing a damaged battery cell 190 from electrical connection with the battery assembly 180. This may provide protection before an electrical input is received by the plurality of interconnecting units 160.

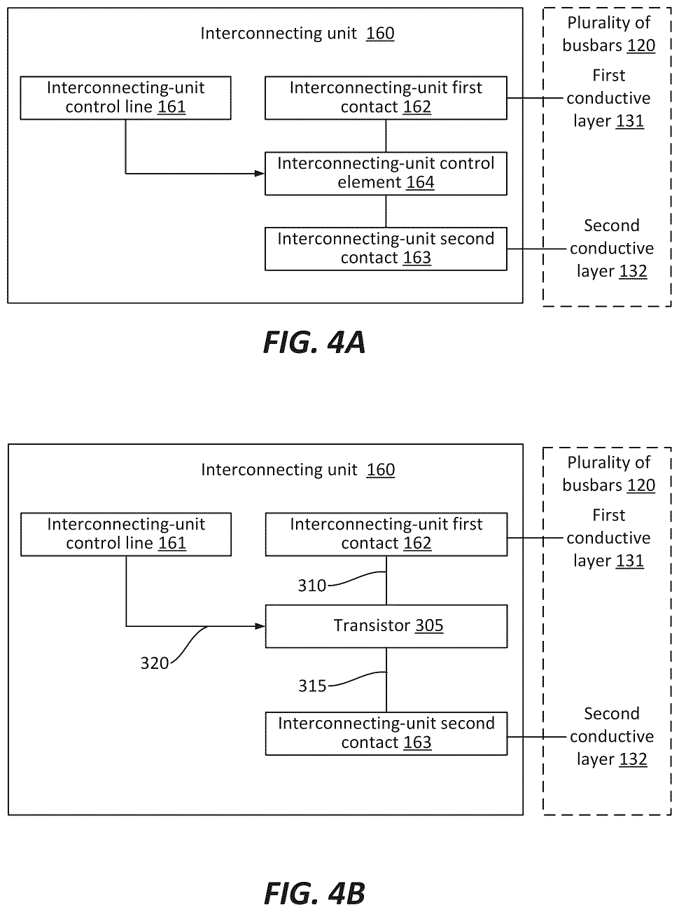

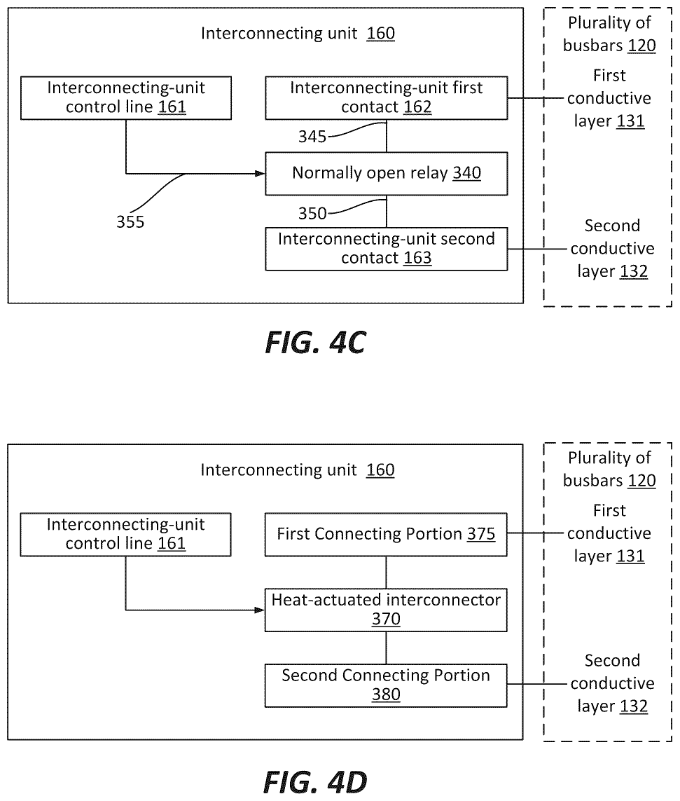

### FIGS. 4A-4C: Examples of Interconnecting Units

Specific examples of interconnecting units will now be described in detail with reference to FIGS. 4A-4D. FIG. 4A presents a schematic block diagram illustrating the relationships of components general to the interconnecting unit examples. Each one of the plurality of interconnecting units 160 comprises an interconnecting-unit control element 164 that is electrically connected to an interconnecting-unit first contact 162, an interconnecting-unit second contact 163, and an interconnecting-unit control line 161. As described above, each one of the plurality of interconnecting units 160 is electrically connected to both a first conductive layer 131 and second conductive layer 132 of the plurality of busbars 120. As shown in FIG. 4A, more specifically, the interconnecting-unit first contact 162 is electrically connected to a first conductive layer 131 and the interconnecting-unit second contact 163 is electrically connected to a second conductive layer 132. Different electrical attachments are within the scope, including but not limited to a weld, a conductive pressure-sensitive adhesive, and a conductive curable adhesive. The interconnecting-unit control element 164 is configured to provide electrical insulation between the interconnecting-unit first contact 162 and interconnecting-unit second contact 163 until an electrical input is received via the interconnecting-unit control line 161. The interconnecting-unit control element 164 is configured to electrically connect the interconnecting-unit first contact 162 and interconnecting-unit second contact 163 after receiving an electrical input via the interconnecting-unit control line 161. When the interconnecting-unit first contact 162 and interconnecting-unit second contact 163 are electrically connected, the first conductive layer 131 and second conductive layer 132 will be in electrical communication.

In some examples, each of the plurality of interconnecting units 160 reversibly electrically connect the first conductive layer 131 and second conductive layer 132. In other words, at least one of the plurality of interconnecting units 160 is configured to electrically connect the two of the plurality of busbars 120 it is connected to after receiving the electrical input through the interconnecting-unit control line 161 and configured to electrically disconnect the two of the plurality of busbars 120 again when the electrical input ceases. A multilayered flexible interconnect circuit 100 comprising reversibly connecting interconnecting-unit control elements 164 may provide advantages in operation. For example, if more battery cells fail after one interconnecting-unit control element 164 is configured to connect two of the plurality of busbars 120, the interconnecting-unit control element 164 may be re-configured if needed to change the routing of electrical current when other interconnecting-unit control elements 164 are configured to connect busbars.

An example of a reversibly connecting interconnecting-unit control element 164 is shown schematically in FIG. 4B. In FIG. 4B, the interconnecting-unit control element 164 is a transistor 305. In this example, the transistor 305 comprises three electrical connections: a source 310, a drain 315, and a gate 320. In FIG. 4B, the source 310 is electrically connected to the interconnecting-unit first contact 162 and the drain 315 is electrically connected to the interconnecting-unit second contact 163. In other examples, the source 310 is electrically connected to the interconnecting-unit second contact 163 and the drain 315 is electrically connected to the interconnecting-unit first contact 162. When no electrical input greater than the turn-on voltage for the transistor 305 is received at the gate 320 via the interconnecting-unit control line 161, the transistor 305 provides a high-impedance resistance to electric current flow between the source 310 and the drain 315. When an electrical input greater than the turn-on voltage for the transistor 305 is received at the gate 320, the transistor 305 allows current to pass from the source 310 to the drain 315. This configures the one of the plurality of interconnecting units 160 to electrically connect the first conductive layer 131 and second conductive layer 132. In some examples, the electrical input has a voltage of 0.5-12 V, 1-9 V, or even 3-5 V. In some examples, the power passing from the interconnecting-unit first contact 162 to the interconnecting-unit second contact 163 through the transistor 305 is 0.2-8 kilowatts (kW), 0.3-5 kW, or even 1-4 kW.

In some examples, the transistor 305 is an external electrical component attached to the multilayered flexible interconnect circuit 100 by soldering, welding, or a conductive adhesive. In these examples, the construction of the multilayered flexible interconnect circuit 100 may provide benefits of simplified manufacturing. The conductor layers to which the source 310, drain 315, and gate 320 are connected to may be designed with thickness optimized for making soldered joints. In other examples, the transistor 305 is fabricated within one of the layers of the multilayered flexible interconnect circuit 100.

In some examples, each of the plurality of interconnecting units 160 is a normally-open relay 340. In these examples, this may provide benefits of lower manufacturing cost and design flexibility. Normally-open relays may be lower in cost than transistors designed for the same maximum electrical current service. In addition, a larger number of suitable normally-open relays may be available than transistors, which may provide improved design flexibility. However, normally-open relays may have larger packages than transistors, requiring greater space on the multilayered flexible interconnect circuit 100. The normally-open relay 340 comprises a first pole 345, a second pole 350, and an actuation lead 355, as shown schematically in FIG. 4D. The first pole 345 and the second pole 350 are electrically disconnected when no electrical input is applied to the actuation lead 355. The first pole 345 and the actuation lead 355 may are electrically connected when some electrical inputs are applied to the actuation lead 355. The properties of the electrical inputs required to connect the first pole 345 and the second pole 350 depend on the design of the normally-open relay 340. The first pole 345 is electrically interconnected with either of the first tab portion 126 of the first busbar 121 and the second tab portion 127 of the second busbar 122. The second pole 350 is electrically interconnected with the other of either the first tab portion 126 of the first busbar 121 and the second tab portion 127 of the second busbar 122. The actuation lead 355 is electrically interconnected with the interconnecting-unit control line 161. Each normally-open relay 340 is configured to reversibly electrically connect the first busbar 121 and the second busbar 122 after receiving the electrical input through the actuation lead 355. In some examples, the normally-open relay 340 is an external electrical component attached to the multilayered flexible interconnect circuit 100 by soldering, welding, or a conductive adhesive.

In some examples, each one of the plurality of interconnecting units 160 comprises one or more voids 136 and an external pressure component 170, as shown in FIG. 2F. The one or more voids 136 creates an open volume from the interconnecting-unit first contact 162 to the interconnecting-unit second contact 163. The external pressure component 170 is electrically connected to the interconnecting-unit control line 161. When no electrical input is received by the external pressure component 170, the one of the plurality of interconnecting units 160 physically separates the interconnecting-unit first contact 162 and the interconnecting-unit second contact 163. The external pressure component 170 is configured to apply pressure to press the interconnecting-unit first contact 162 and the interconnecting-unit second contact 163 towards one another. When this pressure is applied, the one of the plurality of interconnecting units 160 is compressed and the interconnecting-unit first contact 162 and the interconnecting-unit second contact 163 make physical and electrical contact at the one or more voids 136. The thickness and compression resistance of the material of the one of the plurality of interconnecting units 160 and the number, diameter, and arrangement of the one or more voids 136 can be chosen to minimize contact of the interconnecting-unit first contact 162 to the interconnecting-unit second contact 163 when no pressure is applied. These same qualities can also be chosen to maximize the likelihood and quality of the electrical connection made when pressure is applied. For example, an arrangement of a larger number of smaller diameter voids may better prevent unwanted electrical contact than one larger diameter void. The thickness of the one of the plurality of interconnecting units 160 in the direction separating the interconnecting-unit first contact 162 and the interconnecting-unit second contact 163 may be chosen to be sufficiently thick to prevent sparking between the contacts at the highest expected voltage difference between the two.

In some examples, each of the plurality of interconnecting units 160 is configured to irreversibly electrically connect the first conductive layer 131 and second conductive layer 132. A multilayered flexible interconnect circuit 100 comprising irreversibly connecting interconnecting-unit control elements 164 may provide advantages in operation. For example, continuous electrical current must be applied to maintain an electrical input to keep a reversibly connecting interconnecting-unit control element 164. However, once an irreversibly connecting interconnecting-unit control element 164 connects a first conductive layer 131 and a second conductive layer 132, no further electrical current is required to maintain the connection. In this way, more stored electrical power in the battery assembly 180 or an auxiliary power source can be preserved. This may be especially desirable in operation of a limp-home mode for an electric vehicle in a situation where many battery cells 190 have been damaged.

In some examples, each one of the plurality of interconnecting units 160 is a heat-actuated interconnector 370. In these examples, each heat-actuated interconnector 370 comprises a first connecting portion 375, a second connecting portion 380, a meltable portion 385, and a heating element 390. The first connecting portion 375 is electrically interconnected with either the first tab portion 126 of the first busbar 121 and the second tab portion 127 of the second busbar 122. The second connecting portion 380 is electrically interconnected with the other of either the first tab portion 126 of the first busbar 121 and the second tab portion 127 of the second busbar 122. The meltable portion 385 is positioned between the first connecting portion 375 and the second connecting portion 380 as shown in FIG. 2E. In some examples, the heating element 390 is positioned within the meltable portion 385. In some other examples, the heating element 390 is positioned between the meltable portion 385 and either the first connecting portion 375 or the second connecting portion 380. In some other examples, the heating element 390 is positioned either on the opposite side of the first connecting portion 375 from the second connecting portion 380 or on the opposite side of the second connecting portion 380 from the first connecting portion 375. This is also shown in FIG. 2E. The heating element 390 is electrically interconnected with the interconnecting-unit control line 161. The heating element 390 is configured to generate heat and melt the meltable portion 385 after receiving the electrical input through the interconnecting-unit control line 161. When the meltable portion 385 is melted, the first tab portion 126 and second tab portion 127 are irreversibly electrically connected, thereby connecting the first busbar 121 and the second busbar 122. In some examples, external pressure may be applied by an external component to press the first tab portion 126 and the second tab portion 127 together when the meltable portion 385 is melted. The meltable portion 385 may comprise, for example, a heat-activated solder paste.

In some examples, the heating element 390 is either the first connecting portion 375 or the second connecting portion 380. In these examples, the heating element 390 may be patterned to form, for example, a resistive heater. In these examples, when the heating element 390 receives the electrical input, the heating element 390 generates sufficient heat to melt the meltable portion 385. In some examples, in which insulation layer 135 separates the conductor layer of the heating element 390 and the meltable portion 385, the heating element 390 generates sufficient heat to melt the insulation layer 135 positioned between the heating element 390 and the meltable portion 385.

In some examples, the meltable portion 385 may comprise a conductive adhesive. The conductive adhesive may cure when heat is applied by the heating element 390, activating the adhesive and rendering it electrically conductive. In some other examples, the conductive adhesive may cure when an electrical input is received through the interconnecting-unit control line 161, rendering it electrically conductive. The conductive adhesive may be, for example, an anisotropic conductive adhesive such as 124-19C119-44, available from Creative Materials, Ayer, MA.

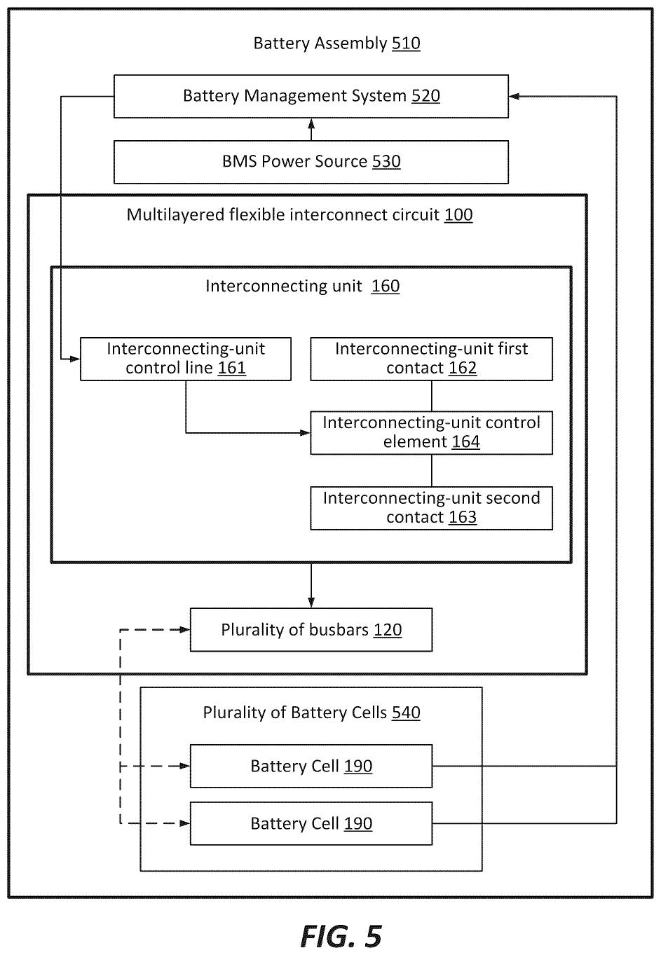

### FIG. 5: Examples of Battery Assemblies

FIG. 5 is a schematic block diagram of a battery assembly 510 comprising a plurality of interconnecting units 160 in accordance with some examples. Battery assembly 510 comprises a battery management system 520, a battery management system power source 530, a multilayered flexible interconnect circuit 100, and a plurality of battery cells 540. The battery management system 520 is electrically connected to the battery management system power source 530. The battery management system power source 530 provides electrical power that the battery management system 520 uses to operate. The multilayered flexible interconnect circuit 100 comprises a plurality of busbars 120 and a plurality of interconnecting units 160. Each of the plurality of busbars 120 comprises a first conductive layer 131 and a second conductive layer 132. Each of the plurality of busbars 120 is defined by a contact portion 125, a first tab portion 126, and a second tab portion 127. The contact portion 125 is formed by both the first conductive layer 131 and the second conductive layer 132, stacked in the contact portion 125. The first tab portion 126 is formed by the first conductive layer 131 such that the second conductive layer 132 does not extend to the first tab portion 126. The second tab portion 127 is formed by the second conductive layer 132 such that the first conductive layer 131 does not extend to the second tab portion 127. The plurality of interconnecting units 160 comprises an interconnecting unit stacked between and connected to each of the first tab portion 126 of the first busbar 121 and the second tab portion 127 of the second busbar 122. Examples of the components and configurations of the plurality of interconnecting units 160 are described above. Each one of the plurality of battery cells 540 comprises two cell terminals 192. Each one of the plurality of busbars 120 is connected to one terminal of each of two of the plurality of battery cells 540. Each interconnecting-unit control line 161 is electrically connected to the battery management system 520. In some examples, the connection between each interconnecting-unit control line 161 and the battery management system 520 is a direct electrical connection. In other examples, the connection is made through an intervening electronic bus that allows selectable addressing of each interconnecting-unit control line 161. Each one of the plurality of interconnecting units 160 maintains the connected first busbar 121 and second busbar 122 that it is connected to electrically disconnected from each other before receiving an electrical input through the interconnecting-unit control line 161. Each one of the plurality of interconnecting units 160 is configured to electrically connect the first busbar 121 and the second busbar 122 it is connected to after receiving the electrical input through the interconnecting-unit control line 161.

In some examples, the multilayered flexible interconnect circuit 100 further comprises a plurality of voltage traces 139. In these examples, each one of the plurality of voltage traces 139 electrically connects one of the plurality of busbars 120 to the battery management system 520.

In some examples, the battery management system power source 530 is an auxiliary battery assembly that is separate from the plurality of battery cells 540. In some examples, one or more battery cells 190 of the plurality of battery cells 540 are the battery management system power source 530. For example, two battery cells 190 from the plurality of battery cells 540, connected in parallel, may be the battery management system power source 530. This example may provide benefits in saving cost, space, and weight by avoiding inclusion of an auxiliary battery assembly in an electric vehicle. In these examples, if one of the two battery cells 190 fails, the other of the two battery cells 190 will still provide sufficient electrical power for the battery management system 520 to operate.

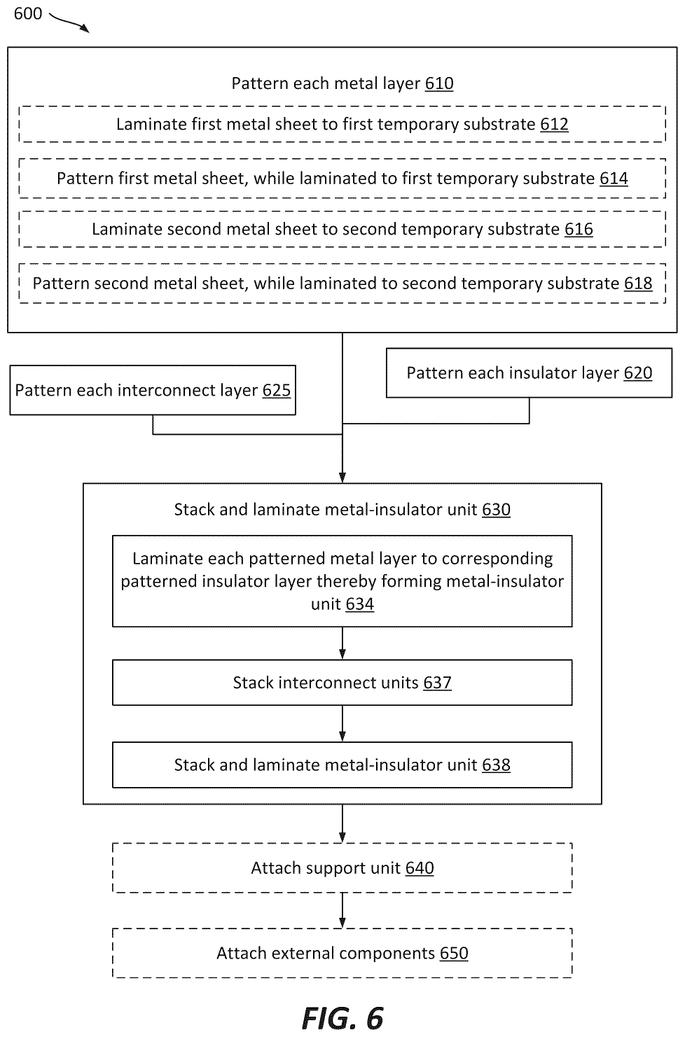

### FIG. 6: Examples of Methods of Fabricating Multilayered Flexible Interconnect Circuits

FIG. 6 is a process flowchart corresponding to method 600 of fabricating a multilayered flexible interconnect circuit 100, in accordance with some examples. Various examples and features of multilayered flexible interconnect circuits 100 are described above. Specifically, a multilayered flexible interconnect circuit 100 comprises at least two conductive layers, e.g., a first conductive layer 131 and a second conductive layer 132. These conductive layers can have different patterns to provide various features described above. Furthermore, the multilayered flexible interconnect circuit 100 also comprises a first outer insulator layer 111, a second outer insulator layer 112, and an inner insulator layer 141 that is used to support and, in some parts, to insulate the first conductive layer 131 and the second conductive layer 132.

Method 600 may comprise (block 610) patterning each conductive layer and, separately, (block 620) patterning each insulator layer, and (block 625) patterning each interconnect unit. In fact, each layer of a multilayered flexible interconnect circuit 100 can be patterned individually prior to laminating these layers together. In some examples, various temporary substrates may be used for these patterning operations. A temporary substrate can be used to support the patterned layer during and after the patterning operation. The temporary substrate is removed when the patterned layers are stacked.

As such, in some examples, method 600 or, more specifically, (block 610) patterning each conductive layer comprises (block 612) laminating a first metal sheet to a first temporary substrate and (block 614) patterning the first metal sheet, while the first metal sheet remains laminated on the first temporary substrate thereby forming a first conductive layer 131. For example, initially, the metal sheet may be a continuous self-supporting metal foil that can be processed and handled without any additional support. The pattern of the first conductive layer 131 may include disjoined components (e.g., busbar portions), narrow conductive traces, and/or other features that can be self-supported. Unlike the first conductive layer 131, the temporary substrate is not patterned (e.g., the temporary substrate may remain as a continuous sheet). In some examples, the same temporary substrate may support multiple instances of first conductive layers 131 (e.g., used for the production of multiple units of multilayered flexible interconnect circuits 100). Various patterning techniques are within the scope. For example, conductive layers can be patterned using chemical etching, mechanical cutting, laser cutting, and the like.

Similarly, method 600 or, more specifically, (block 610) patterning each conductive layer comprises (block 616) laminating a second metal sheet to a second temporary substrate and (block 618) patterning the second metal sheet to a second temporary substrate thereby forming a second conductive layer 132. It should be noted that the pattern of the first conductive layer 131 is different from the pattern of the second conductive layer 132. For example, a busbar (formed by both conductive layers) may have only one conductive layer protruding away and forming a voltage trace.

Method 600 may also comprise (block 620) patterning one or more insulator layers to form various openings. These openings (in the outer insulator layers) are used to provide access to the conductive layers at some locations (e.g., busbars). Furthermore, the openings in inner insulator layers allow the interconnection of the conductive layers at some locations (e.g., busbars). In some examples, after patterning insulator layers, at least one insulator represents a continuous structure (that is able to self-support and does not require any additional structures).

Method 600 may also comprise (block 625) patterning one or more interconnect layers. In some examples, these layers are conductive layers that provide leads or pads for later attachment of interconnect devices (e.g. Transistor 305). In some examples, these layers are polymer or adhesive layers patterned to form components of the plurality of interconnecting units 160 (e.g. Meltable portion 385).

Method 600 further comprises (block 630) stacking and laminating the first conductive layer 131, second conductive layer 132, first outer insulator layer 111, second outer insulator layer 112, and inner insulator layer 141 thereby forming a multilayered flexible interconnect circuit 100. In some examples, this stacking and laminating operation comprises (block 634) laminating the first conductive layer 131 to a first outer insulator layer 111 and/or inner insulator layer 141 and removing any temporary support from the first conductive layer 131. After laminating to one or both of the insulator layers, the first conductive layer 131 is supported by one or both of the insulator layers and the temporary support is no longer needed. Similarly, the second conductive layer 132 may be laminated to a second outer insulator layer 112 and/or inner insulator layer 141 and remove any temporary support from the second conductive layer 132. A combination of a patterned conductive layer (e.g., a first conductive layer 131, a second conductive layer 132) and one or two insulators laminated to this patterned conductive layer may be referred to as a metal-insulator unit. Forming these insulator units prior to forming a full stack of the multilayered flexible interconnect circuit 100 allows the removal of any temporary substrates. Method 600 then proceeds with (block 637), stacking interconnect units. Method 600 then proceeds with (block 638) stacking and laminating these metal-insulator units, each comprising at least one patterned conductive layer. In some examples, a patterned conductive layer comprises two patterned conductive layers, e.g., an inner insulator layer 141 with a first conductive layer 131 laminated to one side and a second conductive layer 132 laminated to the other side.

In some examples, method 600 comprises (block 640) attaching a support unit, e.g., to a first outer insulator layer 111. For example, a support unit may have an adhesive layer interfacing the first outer insulator layer 111 during this operation.

In some examples, method 600 comprises (block 650) attaching external components. These components are components of the plurality of interconnecting units 160. For example, the transistor 305 or the normally-open relay 340 may be soldered or welded to the multilayered flexible interconnect circuit 100.

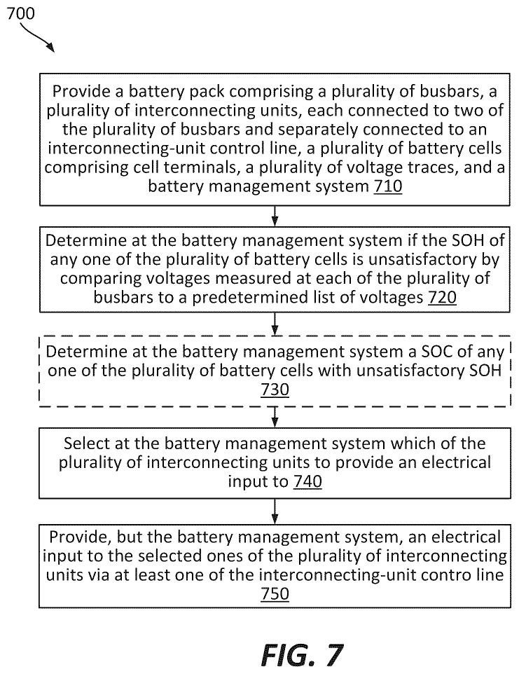

### FIG. 7: Examples of Methods of Operating Battery Packs Comprising Multilayered Flexible Interconnect Circuit with a Plurality of Interconnecting Units

FIG. 7 is a process flow chart corresponding to method 700 of operating a battery assembly 510. Various examples and features of battery assembly 510 have been described above. Method 700 may comments with (block 710) providing a battery pack comprising a plurality of busbars, a plurality of interconnecting units, a plurality of battery cells comprising cell terminals, a plurality of voltage traces, and a battery management system. The battery cell 190 is one component of a battery assembly 510, as shown in FIG. 5. The battery assembly comprises a plurality of busbars 120, a plurality of interconnecting units 160, a plurality of battery cells 540, a plurality of voltage traces 139, and a battery management system 520. The plurality of busbars 120 comprises a first busbar 121 and a second busbar 122. Each of the plurality of interconnecting units 160 is connected to two of the plurality of busbars 120 and separately connected to an interconnecting-unit control line 161. Each one of the plurality of battery cells 540 comprises cell terminals 192. Each of the plurality of busbars 120 comprises a first conductive layer 131 and a second conductive layer 132, and is defined by a contact portion 125, a first tab portion 126, and a second tab portion 127. The contact portion 125 is formed by both the first conductive layer 131 and the second conductive layer 132, stacked in the contact portion 125. The first tab portion 126 is formed by the first conductive layer 131 such that the second conductive layer 132 does not extend to the first tab portion 126. The second tab portion 127 is formed by the second conductive layer 132 such that the first conductive layer 131 does not extend to the second tab portion 127. The cell terminals 192 of each one of the plurality of battery cells 540 are each electrically connected to different ones of the plurality of busbars 120. Each of the interconnecting-unit control lines 161 is electronically connected with the battery management system 520. Each of the voltage traces 139 electrically connects one of the plurality of busbars 120 to the battery management system 520. The plurality of interconnecting units 160 comprise an interconnecting unit 160 stacked between and connected to each of the first tab portion 126 of the first busbar 121 and the second tab portion 127 of the second busbar 122. Each one of the plurality of interconnecting units 160 maintains the two of the plurality of busbars 120 electrically disconnected from each other before receiving an electrical input through the interconnecting-unit control line 161. Each one of the plurality of interconnecting units 160 is configured to electrically connect the two of the plurality of busbars 120 after receiving the electrical input through the interconnecting-unit control line 161. Method 700 may then proceed with (block 720), determining at the battery management system if the state of health (SOH) of any one of the plurality of battery cells is unsatisfactory. The battery management system 520 is configured to determine if the SOH of any of the plurality of battery cells 540 is unsatisfactory by measuring voltages at each of the plurality of busbars 120. In some examples, the battery management system 520 is configured to determine battery cell SOH by comparing voltages measured at each of the plurality of busbars 120 to a predetermined list of voltages.

In some examples, the method may proceed with (block 730) determining at the battery management system 520 the state of charge (SOC) of any one of the plurality of battery cells 540 determined by the battery management system 520 to have unsatisfactory SOH.

Method 700 may proceed by (block 740) selecting at the battery management system 520 which of the plurality of interconnecting units 160 to provide an electrical input to. The features and benefits of activating individual ones of the plurality of interconnecting units 160 have been described above. In some examples, the battery management system 520 may select one or more of the plurality of interconnecting units 160 by comparing the identification of battery cells 190 that have unsatisfactory SOH with a predetermined table that indicates which of the plurality of interconnecting units 160 to activate. If SOC has also been determined by the battery management system 520, this information may also be applied to the selection of which of the plurality of interconnecting units 160 to provide an electrical input to. As described above, it may be desirable to remove a battery cell 190 from electrical connection with the battery assembly 510 by activating one interconnecting unit 160 if the SOC is high and a different interconnecting unit 160 if the SOC is low.

Method 700 may proceed by (block 750) providing, by the battery management system 520, an electrical input to the selected ones of the plurality of interconnecting units 160 via at least one of the interconnecting-unit control line 161.

### Conclusion

It is to be understood that the above description is intended to be illustrative, and not restrictive. For example, the above-described examples (and/or aspects thereof) may be used in combination with each other. In addition, many modifications may be made to adapt a particular situation or material to the teachings presented herein. Dimensions, types of materials, orientations of the various components, and the number and positions of the various components described herein are intended to define parameters of some examples and are by no means limiting and are merely examples. Many examples and modifications within the spirit and scope of the claims will be apparent to those of skill in the art upon reviewing the above description.

1. A multilayered flexible interconnect circuit comprising:
a plurality of busbars, comprising a first busbar and a second busbar, wherein each one of the plurality of busbars is defined by a contact portion, a first tab portion, and a second tab portion;
a plurality of interconnecting-unit control lines, comprising an interconnecting-unit control line; and
a plurality of interconnecting units, wherein:
each one of the plurality of interconnecting units is stacked between and connected to each of the first tab portion of one of the plurality of busbars and the second tab portion of another one of the plurality of busbars and separately connected to an interconnecting-unit control line,
each one of the plurality of interconnecting units is configured to electrically disconnect the first tab portion and the second tab portion before receiving an electrical input through the interconnecting-unit control line, and
each one of the plurality of interconnecting units is configured to electrically connect the first tab portion and the second tab portion after receiving the electrical input through the interconnecting-unit control line.

2. The multilayered flexible interconnect circuit of claim 1, wherein each one of the plurality of interconnecting units is a transistor comprising:
a source electrically interconnected with either the first tab portion of the first busbar and the second tab portion of the second busbar,
a drain electrically interconnected with the other of either the first tab portion of the first busbar and the second tab portion of the second busbar, and
a gate electrically interconnected with the interconnecting-unit control line, wherein:
each transistor is configured to reversibly electrically connect the first busbar and the second busbar after receiving the electrical input through the interconnecting-unit control line.

3. The multilayered flexible interconnect circuit of claim 1, wherein each one of the plurality of interconnecting units is a normally-open relay comprising:
a first pole electrically interconnected with either the first tab portion of the first busbar and the second tab portion of the second busbar,
a second pole electrically interconnected with the other of either the first tab portion of the first busbar and the second tab portion of the second busbar, and
an actuation lead electrically interconnected with the interconnecting-unit control line, wherein:
each normally-open relay is configured to reversibly electrically connect the first busbar and the second busbar after receiving the electrical input through the interconnecting-unit control line.

4. The multilayered flexible interconnect circuit of claim 1, wherein each one of the plurality of interconnecting units is a heat-actuated interconnector comprising:
a first connecting portion electrically interconnected with either the first tab portion of the first busbar and the second tab portion of the second busbar,
a second connecting portion electrically interconnected with the other of either the first tab portion of the first busbar and the second tab portion of the second busbar,
a meltable portion positioned between the first connecting portion and the second connecting portion, and
a heating element electrically interconnected with the interconnecting-unit control line, wherein:
the heating element is configured to melt the meltable portion after receiving the electrical input through the interconnecting-unit control line and thereby irreversibly electrically connect the first busbar and the second busbar.

5. The multilayered flexible interconnect circuit of claim 4, wherein the heating element is positioned between the first connecting portion and the second connecting portion.

6. The multilayered flexible interconnect circuit of claim 4, wherein the heating element is positioned either on an opposite side of the first connecting portion from the second connecting portion or on an opposite side of the second connecting portion from the first connecting portion.

7. The multilayered flexible interconnect circuit of claim 1, wherein:
each one of the plurality of busbars comprises a first conductive layer and a second conductive layer,
the contact portion is formed by both the first conductive layer and the second conductive layer, stacked in the contact portion,
the first tab portion is formed by the first conductive layer such that the second conductive layer does not extend to the first tab portion, and
the second tab portion is formed by the second conductive layer such that the first conductive layer does not extend to the second tab portion.

8. The multilayered flexible interconnect circuit of claim 7, wherein the first conductive layer and second conductive layer are separated from each other in the contact portion by an insulation layer.

9. The multilayered flexible interconnect circuit of claim 7, wherein the first conductive layer and second conductive layer directly interface each other in the contact portion.

10. The multilayered flexible interconnect circuit of claim 9, wherein the first conductive layer and the second conductive layer directly interface each other and are welded to one another in the contact portion.

11. The multilayered flexible interconnect circuit of claim 1, wherein at least one of the plurality of interconnecting units reversibly electrically connects the first tab portion and the second tab portion after receiving the electrical input.

12. The multilayered flexible interconnect circuit of claim 1, wherein at least one of the plurality of interconnecting units is connected to one of the plurality of busbars connected to a terminal of a battery and another one of the plurality of busbars connected to another terminal of the battery.

13. The multilayered flexible interconnect circuit of claim 1, wherein at least one of the plurality of interconnecting units is connected to one of the plurality of busbars connected to a terminal of a battery and another one of the plurality of busbars connected to another terminal of another battery.

14. The multilayered flexible interconnect circuit of claim 1, wherein each of the plurality of interconnecting units irreversibly electrically connects the first tab portion and the second tab portion after receiving the electrical input.

15. The multilayered flexible interconnect circuit of claim 1, wherein the electrical input has a voltage of 1-5 volts.

16. A battery assembly comprising:
a plurality of busbars comprising a first busbar and a second busbar;
a plurality of interconnecting units, each connected to two of the plurality of busbars and separately connected to an interconnecting-unit control line;
a plurality of battery cells comprising cell terminals; and
a battery management system, wherein:
each of the plurality of busbars comprises a first conductive layer and a second conductive layer,
each of the plurality of busbars is defined by a contact portion, a first tab portion, and a second tab portion,
the contact portion is formed by both the first conductive layer and the second conductive layer, stacked in the contact portion,
the first tab portion is formed by the first conductive layer such that the second conductive layer does not extend to the first tab portion,
the second tab portion is formed by the second conductive layer such that the first conductive layer does not extend to the second tab portion,
the cell terminals of each one of the plurality of battery cells are each electrically connected to different ones of the plurality of busbars,
each of the interconnecting-unit control lines is electronically connected with the battery management system,
the plurality of interconnecting units comprise an interconnecting unit stacked between and connected to each of the first tab portion of the first busbar and the second tab portion of the second busbar,
each one of the plurality of interconnecting units maintains the two of the plurality of busbars electrically disconnected from each other before receiving an electrical input through the interconnecting-unit control line, and
each one of the plurality of interconnecting units is configured to electrically connect the two of the plurality of busbars after receiving the electrical input through the interconnecting-unit control line.

17. The battery assembly of claim 16, further comprising a plurality of voltage traces, wherein each of the voltage traces electrically connects one of the plurality of busbars to the battery management system.

18. The battery assembly of claim 16, further comprising a battery management system power source electrically connected to the Battery Management System, wherein the battery management system power source is at least one of the plurality of battery cells.

19. A method of operating a battery assembly, the method comprising:
providing a battery pack comprising:
a plurality of busbars comprising a first busbar and a second busbar;
a plurality of interconnecting units, each connected to two of the plurality of busbars and separately connected to an interconnecting-unit control line;
a plurality of battery cells comprising cell terminals;
a plurality of voltage traces; and
a battery management system, wherein:
each of the plurality of busbars comprises a first conductive layer and a second conductive layer,
each of the plurality of busbars is defined by a contact portion, a first tab portion, and a second tab portion,
the contact portion is formed by both the first conductive layer and the second conductive layer, stacked in the contact portion,
the first tab portion is formed by the first conductive layer such that the second conductive layer does not extend to the first tab portion,
the second tab portion is formed by the second conductive layer such that the first conductive layer does not extend to the second tab portion,
the cell terminals of each one of the plurality of battery cells are each electrically connected to different ones of the plurality of busbars,
each of the interconnecting-unit control lines is electronically connected with the battery management system,
each of the voltage traces electrically connects one of the plurality of busbars to the battery management system,
the battery management system is configured to determine SOH of each of the plurality of battery cells by measuring voltages at each of the plurality of busbars,
the plurality of interconnecting units comprise an interconnecting unit stacked between and connected to each of the first tab portion of the first busbar and the second tab portion of the second busbar,
each one of the plurality of interconnecting units maintains the two of the plurality of busbars electrically disconnected from each other before receiving an electrical input through the interconnecting-unit control line, and
each one of the plurality of interconnecting units is configured to electrically connect the two of the plurality of busbars after receiving the electrical input through the interconnecting-unit control line;
determining at the battery management system if the SOH of any one of the plurality of battery cells is unsatisfactory by comparing voltages measured at each of the plurality of busbars to a predetermined list of voltages;
selecting at the battery management system which of the plurality of interconnecting units to provide an electrical input to; and
providing, by the battery management system, an electrical input to the selected ones of the plurality of interconnecting units via at least one of the interconnecting-unit control line.

20. The method of operating a battery assembly of claim 19, the method further comprising:
determining at the battery management system an SOC of any one of the plurality of battery cells with unsatisfactory SOH.
